(19) United States
(12) Patent Application Publication
(10) Pub. No.: US 2008/0203485 A1
(43) Pub. Date: Aug. 28, 2008

(54) STRAINED METAL GATE STRUCTURE FOR CMOS DEVICES WITH IMPROVED CHANNEL MOBILITY AND METHODS OF FORMING THE SAME

(75) Inventors: Michael P. Chudzik, Danbury, CT (US); Wei He, Fishkill, NY (US); Renee T. Mo, Briarcliff Manor, NY (US); Naim Moumen, Walden, NY (US); Vijay Narayanan, New york, NY (US); Dae-gyu Park, Poughquag, NY (US); Vamsi Paruchuri, New York, NY (US)

Correspondence Address: CANTOR COLBURN LLP - IBM FISHKILL, 20 Church Street, 22nd Floor, Hartford, CT, 06103, US

(73) Assignee: International Business Machines Corporation, Armonk, NY (US)

(21) Appl. No.: 11/680,108

(22) Filed: Feb. 28, 2007

(51) Int. Cl. H01L 29/76; H01L 21/8238

(52) U.S. Cl. 257/369; 438/585; 257/E29.226; 257/E21.632

(57) ABSTRACT

A gate structure for complementary metal oxide semiconductor (CMOS) devices includes a first gate stack having a first gate dielectric layer formed over a substrate, and a first metal layer formed over the first gate dielectric layer. A second gate stack includes a second gate dielectric layer formed over the substrate and a second metal layer formed over the second gate dielectric layer. The first metal layer is formed in manner so as to impart a tensile stress on the substrate, and the second metal layer is formed in a manner so as to impart a compressive stress on the substrate.

### BACKGROUND

The present invention relates generally to semiconductor device processing techniques, and, more particularly, to a strained metal gate structure for complementary metal oxide semiconductor (CMOS) devices yielding improved channel mobility, and methods of forming the same.

Strain engineering techniques have recently been applied to CMOS device manufacturing in order to provide different stresses in P-type MOS (PMOS) devices with respect to N-type MOS (NMOS) devices. For example, a nitride liner of a first type is formed over the PFETs of a CMOS device, while a nitride liner of a second type is formed over the NFETs of the CMOS device. More specifically, it has been discovered that the application of a compressive stress in a PFET channel improves carrier (hole) mobility therein, while the application of a tensile stress in an NFET channel improves carrier (electron) mobility therein, leading to higher on-current and product speed. Thus, the first type nitride liner may be formed over the PFET devices in a manner so as to achieve a compressive stress, while the second type nitride liner may be formed over the NFET devices in a manner so as to achieve a tensile stress.

As transistors continue scale down in physical dimension, there has also been an effort to utilize high-k dielectric gate insulating films and metal gates in order to reduce power consumption through gate leakage current, reduce the equivalent oxide thickness, and reduce inversion thickness. As is the case with conventional polysilicon gate devices, it is desirable to adjust the work function of a gate electrode to be close to either the conduction band or the valence band of silicon, as this reduces the threshold voltage of the transistor, thereby facilitating a high drive current. Thus, dual work function gates are advantageously used in semiconductor devices having both PMOS and NMOS transistors.

Ideally, dual work function metal gates should be compatible with conventional gate dielectric materials and have suitably adjustable work functions. Moreover, the fabrication of metal gates should be easily adaptable to conventional semiconductor device fabrication processes. It has proven challenging, however, to simply deposit and etch metals to form gate structures. For instance, it can be difficult to find etchants and etch conditions where gate metals can be etched with high selectivity, (i.e., without damaging the underlying gate insulator and silicon substrate). Additionally, if two different metals are used to provide dual work function gates, a deposit-and-etch fabrication scheme entails the further complications of selectively etching one gate metal over another gate metal, or etching both metal gates simultaneously.

In order to protect the gate dielectric when a metal layer is patterned and etched, some manufacturers have proposed depositing an etch barrier layer between the gate dielectric and the metal layers. This process not only adds to the thickness to the gate dielectric, but also involves additional processing steps. To avoid the need to selectively etch one metal over another metal, others have proposed using a single metal, having a midrange work function, as the gate material. Unfortunately, transistors having such single-metal gate electrodes have undesirably high threshold voltages.

Still others have proposed a gate-last fabrication scheme in which a conventional transistor is initially fully manufactured, including the fabrication of a polysilicon gate with underlying, implanted doped regions. The polysilicon gate and underlying gate dielectric are then removed to provide a gate opening. A new gate dielectric is then conformally deposited on the sides and bottom of the gate opening, followed by filling the gate opening with a metal, to replace the polysilicon gate. In such gate-last fabrication schemes, dopants are implanted into various components of the transistor (e.g., the source and drain) before the new gate dielectric and replacing metal gate is formed. As such, gate-last fabrication schemes typically require that all subsequent steps to depositing the gate metal and gate dielectric are implemented at low temperatures (e.g., below about 700° C.) to prevent the diffusion of dopants.

However, regardless of the specific techniques used for fabrication of metal gate devices, it is still desirable to be able to take advantage of the above discussed benefits of strained silicon channel engineering, but in a manner that may easily be incorporated into existing processes of record.

### SUMMARY

The foregoing discussed drawbacks and deficiencies of the prior art are overcome or alleviated by a gate structure for complementary metal oxide semiconductor (CMOS) devices. In an exemplary embodiment, the structure includes a first gate stack having a first gate dielectric layer formed over a substrate, and a first metal layer formed over the first gate dielectric layer; and a second gate stack having a second gate dielectric layer formed over the substrate and a second metal layer formed over the second gate dielectric layer; wherein the first metal layer is formed in manner so as to impart a tensile stress on the substrate, and the second metal layer is formed in a manner so as to impart a compressive stress on the substrate.

In another embodiment, a complementary metal oxide semiconductor (CMOS) device includes an NFET metal gate stack structure having a compressive metal layer formed over a substrate, and a PFET metal gate stack structure having a tensile metal layer formed over the substrate. The NFET and PFET metal gate stack structures each including a high-k gate dielectric layer, and wherein the compressive metal layer of the NFET metal gate stack structure is configured to impart a tensile stress on the substrate, and the tensile metal layer of the PFET metal gate stack structure is configured to impart a compressive stress on the substrate.

In another embodiment, a method of forming a gate structure for a complementary metal oxide semiconductor (CMOS) device includes forming a gate dielectric layer over a semiconductor substrate; forming a first metal layer over the gate dielectric layer; forming a cap layer over the first metal layer; removing the cap layer and first metal layer over a PFET portion of the device, leaving the cap layer and first metal layer over an NFET portion of the device; forming a second metal layer over the NFET and PFET portions of the device; and removing the second metal from the NFET portion of the device; wherein the first metal layer is formed in manner so as to impart a tensile stress on the substrate, and the second metal layer is formed in a manner so as to impart a compressive stress on the substrate.

In still another embodiment, a method of forming a gate structure for a complementary metal oxide semiconductor (CMOS) device includes forming a gate dielectric layer over a semiconductor substrate; forming a first metal layer over the gate dielectric layer; forming a cap layer over the first metal layer; removing the cap layer and first metal layer over a PFET portion of the device, leaving the cap layer and first metal layer over an NFET portion of the device; forming a second metal layer over the NFET and PFET portions of the device; and removing the second metal from the NFET portion of the device; wherein the second metal layer is formed over PFET portions of the device by damascene filling; and wherein the first metal layer is formed in manner so as to impart a tensile stress on the substrate, and the second metal layer is formed in a manner so as to impart a compressive stress on the substrate.

### BRIEF DESCRIPTION OF THE DRAWINGS

Referring to the exemplary drawings wherein like elements are numbered alike in the several Figures:

FIGS. 1(a) through 1(f) are a sequence of cross sectional views illustrating a method of forming CMOS devices with tuned stressed metal gates, in accordance with an embodiment of the invention; and

FIG. 2 is a cross sectional view illustrating a method of forming CMOS devices with tuned stressed metal gates, in accordance with an alternative embodiment of the invention.

### DETAILED DESCRIPTION

Disclosed herein is a method for improving channel mobility of metal gate complementary metal oxide semiconductor (CMOS) devices. Briefly stated, the embodiments disclosed herein provide for the formation of metal gates with residual strain therein, the direction of which is dependent upon whether the gate is associated with an NMOS device or a PMOS device. By depositing a metal gate directly on a gate dielectric layer, in a manner such that the gate has a directional, residual strain according to the conductivity type of the transistor, carrier mobility is enhanced beyond the conventional methods described above. Moreover, the strained metal gates may be formed in a manner compatible with existing metal gate fabrication processes.

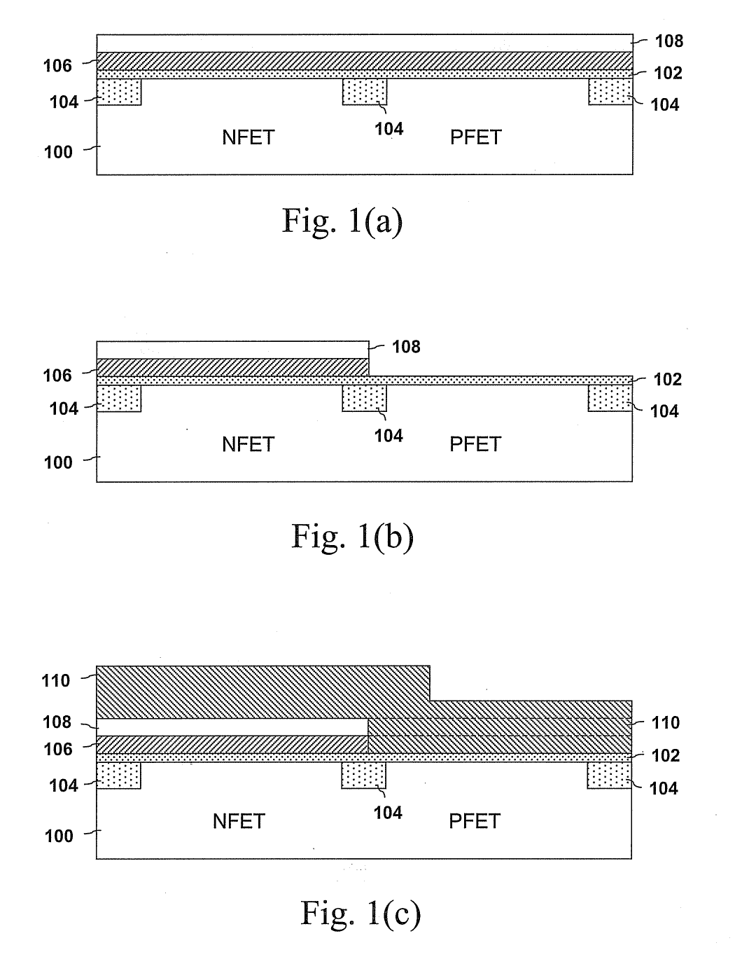

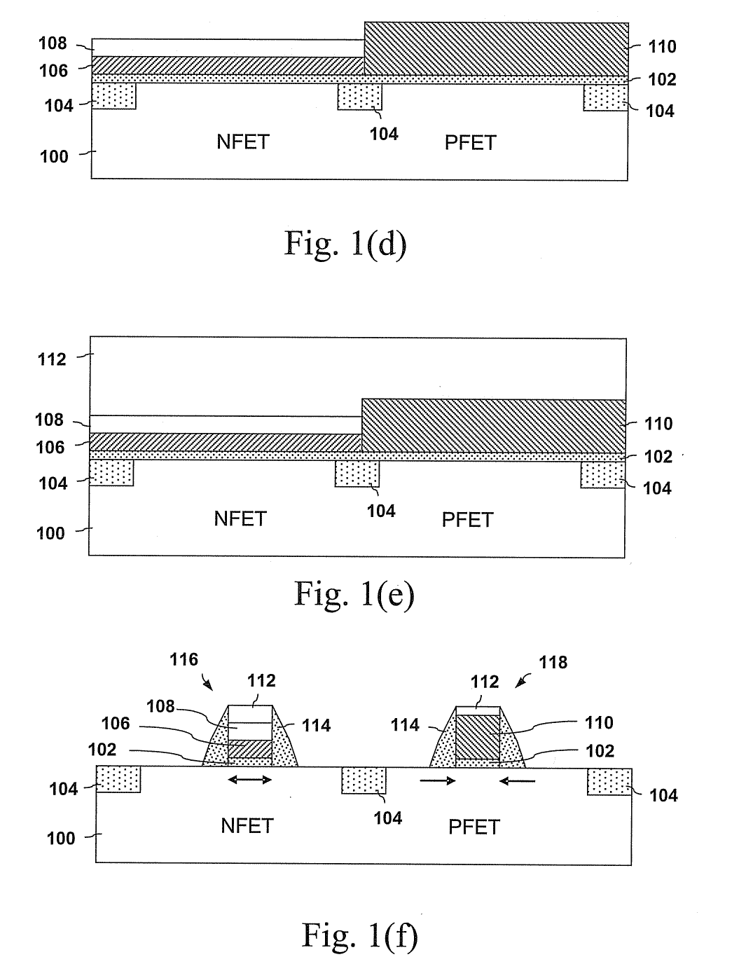

Referring initially to FIGS. 1(a) through 1(e), there is shown a sequence of cross sectional views illustrating a method of forming CMOS devices with tuned stressed metal gates, in accordance with an embodiment of the invention. As shown in FIG. 1(a), a semiconductor substrate 100 has a gate dielectric layer 102 formed thereon. The substrate 100 may include a bulk silicon or a silicon-on-insulator (SOI) structure, for example, although other semiconductor materials such as germanium, silicon germanium, silicon germanium-on-insulator, silicon carbide, indium antimonide, indium arsenide, indium phosphide, gallium arsenide, gallium aresenide, etc. are also contemplated.

In an exemplary embodiment, the gate dielectric layer 102 is formed from a high-k material such as, for example, hafnium oxide, hafnium silicon oxide, lanthanum oxide, zirconium oxide, zirconium silicon oxide, tantalum oxide, barium strontium titanium oxide, barium titanium oxide, strontium titanium oxide, yttrium oxide, aluminum oxide, lead scandium tantalum oxide, and lead zinc niobate. However, other gate dielectric materials that serve to reduce gate leakage may also be utilized.

As further illustrated in FIG. 1(a), the substrate 100 has a plurality of shallow trench isolation (STI) regions 104 formed therein, which define complementary CMOS device regions NFET and PFET. The gate dielectric layer 102 may be formed on the substrate 100 and STI regions 104 using a conventional deposition method, e.g., a chemical vapor deposition (CVD), low pressure CVD, plasma enhanced CVD (PECVD), atomic layer CVD or physical vapor deposition (PVD) process. Following the deposition of an optional NMOS work function tuning layer (not shown), a first metal layer 106 is formed over the gate dielectric layer 102. In the embodiment depicted, the first metal layer 106 is used for the NFET regions of the device and, as such, is deposited in a manner so as to exhibit a tensile stress on the substrate 100. Stated another way, the first metal layer 106 is formed as a compressive film.

In one exemplary embodiment, the first metal layer 106 is a titanium nitride (TiN) film, formed at a thickness of about 10-200 angstroms (Å). Formed at such an exemplary thickness, and at a relatively high density with less oxygen content, the compressive first metal layer 106 (in addition to having an appropriately tailored work function for an NFET device) is formed an a manner so as to impart a tensile stress on the transistor channel below the gate. Additional information regarding the formation of a dense, compressive TiN film may be found in “Handbook of Thin Film Process Technology,” David Glocker ed., Institute of Physics Publishing, Philadelphia, 1998, the contents of which are incorporated herein in their entirety.

Following the formation of the first metal layer 106, a cap layer 108 (e.g., anywhere between 50-200 Å of amorphous silicon) is then formed over the first metal layer 106 to protect selected portions thereof from subsequent etching. Then, as shown in FIG. 1(b), the device is patterned such that the cap layer 108 and compressive first metal layer 106 is removed over the PFET portions of the device. Referring to FIG. 1(c), following the deposition of an optional PMOS work function tuning layer (not shown), a second metal layer 110 is deposited over the NFET region of the device, as well as over the exposed gate dielectric layer 102 in the PFET region of the device.

In an exemplary embodiment, the second metal layer 110 is also a titanium nitride (TiN) film, formed at a total thickness of about 50-500 Å. In one preferred embodiment, the thickness of the NFET and PFET metals are substantially equivalent, e.g., roughly 400-500 Å. Optionally, the second metal layer 106 can be formed in a single deposition step (unlayered) or through several layered deposition steps. In either case, the second metal layer 110 is formed as a more porous structure with respect to the first metal layer 106, thus resulting in a tensile film that imparts a compressive stress on the transistor channel below the gate. Advantageously, the thicker, tensile TiN film 110 having a higher oxygen content with respect to the compressive TiN film 106 has the added benefit of a more appropriately tailored work function for a PFET metal gate. (Eduard Cartier, IBM, VLSI Conference, 2005)

Referring next to FIG. 1(d), the device is once again patterned such that the tensile second metal layer 110 (and optional tuning layer) is removed from the NFET region. Then, in FIG. 1(e), a layer of polysilicon 112 (e.g., about 500-1000 Å in thickness) may be formed over the device to complete the gate stack structure for both the NFET and PFET. Where an amorphous silicon cap layer 108 is included in the NFET stack, the deposition of the polysilicon layer 112 may be accompanied with a suitable, in-situ hydrogen bake and/or dilute hydrofluoric acid (DHF) preclean step to ensure good adherence of the polysilicon layer 112 to the amorphous silicon layer 108.

Finally, FIG. 1(f) illustrates the gate contact patterning and definition, accompanied by sidewall spacer 114 formation as known in the art prior to source/drain dopant implantation. Thus configured, a novel CMOS gate structure is defined in which the resulting NFET gate stack 116 includes the optional polysilicon layer 112 and amorphous silicon cap layer 108, in addition to the first TiN (compressive) metal layer 106, and gate dielectric layer 102. The PFET gate stack 118 includes the optional polysilicon layer 112, in addition to the second TiN (tensile) metal layer 110 and gate dielectric layer 102.

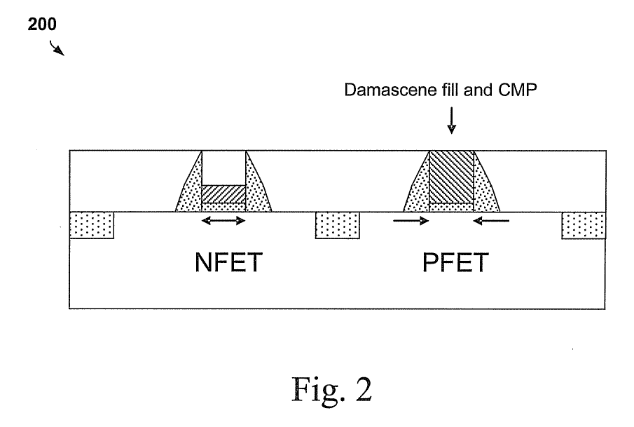

As indicated above, the dual stressed metal gate structure disclosed herein is compatible with other variations and techniques with respect to metal gate formation. Another such example is the above discussed gate-last fabrication scheme, in which transistor is initially fully manufactured, including the fabrication of a polysilicon gate with underlying, implanted doped regions. The polysilicon gate and underlying gate dielectric are then removed to provide a gate opening. A new gate dielectric is then conformally deposited on the sides and bottom of the gate opening, followed by filling the gate opening with a metal, to replace the polysilicon gate. An exemplary dual stressed metal gate structure 200 formed in this manner is illustrated in FIG. 2.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A gate structure for complementary metal oxide semiconductor (CMOS) devices, comprising:
a first gate stack comprising a first gate dielectric layer formed over a substrate, and a first metal layer formed over the first gate dielectric layer; and
a second gate stack comprising a second gate dielectric layer formed over the substrate and a second metal layer formed over the second gate dielectric layer;
wherein the first metal layer is formed in manner so as to impart a tensile stress on the substrate, and the second metal layer is formed in a manner so as to impart a compressive stress on the substrate.

2. The gate structure of claim 1, wherein the first and second metal layers comprise the same material.

3. The gate structure of claim 2, wherein the first and second metal layer comprise titanium nitride (TiN).

4. The gate structure of claim 1, wherein:
the first gate stack comprises an NFET gate stack, with the first metal layer being a compressive film; and
the second gate stack comprises a PFET gate stack, with the second metal layer being a tensile film.

5. The gate structure of claim 4, wherein the NFET gate stack further comprises a compressive TiN film formed over the first gate dielectric layer and a cap layer formed over the compressive TiN film.

6. The gate structure of claim 5, wherein the PFET gate stack structure further comprises a tensile TiN film formed over the second gate dielectric layer.

7. The gate structure of claim 6, wherein the tensile TiN film of the PFET gate stack structure is formed at a greater thickness than the compressive TiN film of the NFET gate stack structure.

8. The gate structure of claim 7, wherein the compressive TiN film of the NFET gate stack structure is formed at a thickness of about 100 to about 200 angstroms (Å), and wherein tensile TiN film of the PFET gate stack structure is formed at a thickness of about 400 to about 500 Å.

9. The gate structure of claim 6, wherein the first and second gate dielectric layers comprise the same material.

10. The gate structure of claim 8, wherein the first and second gate dielectric layers are a high-k material comprising at least one of: hafnium oxide, hafnium silicon oxide, lanthanum oxide, zirconium oxide, zirconium silicon oxide, tantalum oxide, barium strontium titanium oxide, barium titanium oxide, strontium titanium oxide, yttrium oxide, aluminum oxide, lead scandium tantalum oxide, and lead zinc niobate.

11. A complementary metal oxide semiconductor (CMOS) device, comprising:
an NFET metal gate stack structure comprising a compressive metal layer formed over a substrate;
a PFET metal gate stack structure comprising a tensile metal layer formed over the substrate; and
the NFET and PFET metal gate stack structures each including a high-k gate dielectric layer;
wherein the compressive metal layer of the NFET metal gate stack structure is configured to impart a tensile stress on the substrate, and the tensile metal layer of the PFET metal gate stack structure is configured to impart a compressive stress on the substrate.

12. The CMOS device of claim 11, wherein both the tensile and compressive metal layers comprise titanium nitride (TiN).

13. The CMOS device of claim 12, wherein the high-k gate dielectric layer of the NFET and PFET metal gate stack structures comprises at least one of: hafnium oxide, hafnium silicon oxide, lanthanum oxide, zirconium oxide, zirconium silicon oxide, tantalum oxide, barium strontium titanium oxide, barium titanium oxide, strontium titanium oxide, yttrium oxide, aluminum oxide, lead scandium tantalum oxide, and lead zinc niobate.

14. The CMOS device of claim 13, wherein the NFET metal gate stack further comprises an amorphous silicon cap layer formed over the compressive metal layer and a polysilicon top layer formed over the cap layer.

15. The CMOS device of claim 14, wherein the PFET metal gate stack further comprises a polysilicon top layer formed over the tensile metal layer.

16. The CMOS device of claim 15, wherein the tensile TiN film of the PFET gate stack is formed at a greater thickness than the compressive TiN film of the NFET gate stack structure.

17. The CMOS device of claim 16, wherein the compressive TiN film of the NFET gate stack structure is formed at a thickness of about 100 to about 200 angstroms (Å), and wherein tensile TiN film of the PFET gate stack structure is formed at a thickness of about 400 to about 500 Å.

18. A method of forming a gate structure for a complementary metal oxide semiconductor (CMOS) device, the method comprising:
forming a gate dielectric layer over a semiconductor substrate;
forming a first metal layer over the gate dielectric layer;
forming a cap layer over the first metal layer;
removing the cap layer and first metal layer over a PFET portion of the device, leaving the cap layer and first metal layer over an NFET portion of the device;
forming a second metal layer over the NFET and PFET portions of the device; and
removing the second metal from the NFET portion of the device;
wherein the first metal layer is formed in manner so as to impart a tensile stress on the substrate, and the second metal layer is formed in a manner so as to impart a compressive stress on the substrate.

19. The method of claim 18, further comprising patterning and etching an NFET gate stack and a PFET gate stack, the NFET gate stack comprising the gate dielectric layer, the first metal layer and the cap layer, and the PFET gate stack comprising the gate dielectric layer and the second metal layer.

20. The method of claim 19, wherein the first metal layer of the NFET gate stack comprises a compressive titanium nitride (TiN) film and the second metal layer of the PFET gate stack comprises a tensile TiN film.

21. The method of claim 20, wherein the tensile TiN film of the PFET gate stack structure is formed at a greater thickness than the compressive TiN film of the NFET gate stack structure.

22. The method of claim 21, wherein the compressive TiN film of the NFET gate stack structure is formed at a thickness of about 10 to about 500 angstroms (Å), and wherein tensile TiN film of the PFET gate stack structure is formed at a thickness of about 50 to about 500 Å.

23. The method of claim 21, wherein the compressive TiN film of the NFET gate stack structure is formed at a thickness of about 400 to about 500 angstroms (Å), and wherein tensile TiN film of the PFET gate stack structure is formed at a thickness of about 400 to about 500 Å.

24. The method of claim 20, wherein the first and second gate dielectric layers comprise the same material.

25. The method of claim 24, wherein the first and second gate dielectric layers are a high-k material comprising at least one of: hafnium oxide, hafnium silicon oxide, lanthanum oxide, zirconium oxide, zirconium silicon oxide, tantalum oxide, barium strontium titanium oxide, barium titanium oxide, strontium titanium oxide, yttrium oxide, aluminum oxide, lead scandium tantalum oxide, and lead zinc niobate.

26. The method of claim 20, further comprising forming a polysilicon top layer over NFET and PFET portions of the device prior to patterning and etching the NFET and PFET gate stacks.

27. A method of forming a gate structure for a complementary metal oxide semiconductor (CMOS) device, the method comprising:
forming a gate dielectric layer over a semiconductor substrate;
forming a first metal layer over the gate dielectric layer;
forming a cap layer over the first metal layer;
removing the cap layer and first metal layer over a PFET portion of the device, leaving the cap layer and first metal layer over an NFET portion of the device;
forming a second metal layer over the NFET and PFET portions of the device; and
removing the second metal from the NFET portion of the device;
wherein the second metal layer is formed over PFET portions of the device by damascene filling; and
wherein the first metal layer is formed in manner so as to impart a tensile stress on the substrate, and the second metal layer is formed in a manner so as to impart a compressive stress on the substrate.
